(19) United States
(12) Patent Application Publication
(10) Pub. No.: US 2025/0301745 A1
(43) Pub. Date: Sep. 25, 2025

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Byungho MOON, Suwon-si (KR); KYOUNG-MI PARK, Suwon-si (KR); YOUNGJIN YANG, Suwon-si (KR); Kyung Hee CHO, Suwon-si (KR)

(73) Assignee: SAMSUNG ELECTRONICS CO., LTD., Suwon-si (KR)

(21) Appl. No.: 18/937,612

(22) Filed: Nov. 5, 2024

(30) Foreign Application Priority Data
Mar. 21, 2024 (KR) 10-2024-0039367

(51) Int. Cl. H01L 29/66; H01L 29/06; H01L 29/423; H01L 29/775; H01L 29/786

(52) U.S. Cl. CPC H10D 64/018; H10D 30/43; H10D 30/6735; H10D 30/6757; H10D 62/121; H10D 30/014

(57) ABSTRACT

A semiconductor device includes a first channel pattern and a second channel pattern on a substrate, where the first channel pattern includes a plurality of first semiconductor patterns spaced apart in a first direction that is perpendicular to an upper surface of the substrate, and where the second channel pattern includes a plurality of second semiconductor patterns spaced apart in the first direction, and an isolation pattern between the first channel pattern and the second channel pattern, where the isolation pattern includes a first region, a second region contacting each of the first channel pattern and the second channel pattern, and a third region at a level that is higher than an uppermost first semiconductor pattern among the plurality of first semiconductor patterns and an uppermost second semiconductor pattern among the plurality of second semiconductor patterns.

### CROSS-REFERENCE TO RELATED APPLICATIONS

This application is based on and claims priority under 35 U.S.C. § 119 to Korean Patent Application No. 10-2024-0039367, filed on Mar. 21, 2024, in the Korean Intellectual Property Office, the disclosure of which is incorporated by reference herein in its entirety.

### BACKGROUND

Example embodiments of the disclosure relate to a semiconductor device and a method for manufacturing the same, and more particularly, to a semiconductor device including a field effect transistor (FET) and a method for manufacturing the same.

A semiconductor device may include an integrated circuit including metal-oxide-semiconductor FETs (MOSFETs). As a size and a design rule of the semiconductor device are gradually reduced, scaling down the metal-oxide-semiconductor FETs may be gradually being accelerated. As the MOSFETs are scaled down, operation characteristics of the semiconductor device may deteriorate.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device having improved electrical characteristics.

Additional aspects will be set forth in part in the description which follows and, in part, will be apparent from the description, or may be learned by practice of the presented embodiments.

According to an aspect of an example embodiment, a semiconductor device may include a first channel pattern and a second channel pattern on a substrate, where the first channel pattern includes a plurality of first semiconductor patterns spaced apart in a first direction that is perpendicular to an upper surface of the substrate, and where the second channel pattern includes a plurality of second semiconductor patterns spaced apart in the first direction, and an isolation pattern between the first channel pattern and the second channel pattern, where the isolation pattern may include a first region, a second region contacting each of the first channel pattern and the second channel pattern, and a third region at a level that is higher than an uppermost first semiconductor pattern among the plurality of first semiconductor patterns and an uppermost second semiconductor pattern among the plurality of second semiconductor patterns, in a second direction parallel to the upper surface of the substrate, a width of the third region of the isolation pattern is greater than a width of the first region of the isolation pattern, and, in the second direction, a width of the second region of the isolation pattern is greater than the width of the first region of the isolation pattern.

According to an aspect of an example embodiment, a semiconductor device may include a first channel pattern and a second channel pattern on a substrate, an isolation pattern between the first channel pattern and the second channel pattern, the isolation pattern including a first region and a second region contacting the first channel pattern and the second channel pattern, an inner gate spacer on side surfaces of the first region of the isolation pattern opposite each other in a first direction parallel to an upper surface of the substrate, and a gate dielectric pattern on side surfaces of the inner gate spacer, where the first region of the isolation pattern is spaced apart from the gate dielectric pattern, and in the first direction, a width of the second region of the isolation pattern is greater than a width of the first region of the isolation pattern.

According to an aspect of an example embodiment, a semiconductor device may include a first channel pattern and a second channel pattern on a substrate, where the first channel pattern includes a plurality of first semiconductor patterns spaced apart in a first direction that is perpendicular to an upper surface of the substrate, and where the second channel pattern includes a plurality of second semiconductor patterns spaced apart in the first direction, a first source/drain pattern connected to the first channel pattern and a second source/drain pattern connected to the second channel pattern, an isolation pattern between the first channel pattern and the second channel pattern, and between the first source/drain pattern and the second source/drain pattern, a first gate electrode at least partially surrounding the first channel pattern and a second gate electrode at least partially surrounding the second channel pattern, and a power transmission network layer on a lower surface of the substrate, where the isolation pattern may include a first region, a second region contacting each of the first channel pattern and the second channel pattern, and a third region at a level that is higher than an uppermost first semiconductor pattern among the plurality of first semiconductor patterns and an uppermost second semiconductor pattern among the plurality of second semiconductor patterns, where in a second direction parallel to the upper surface of the substrate, a width of the third region of the isolation pattern is greater than a width of the first region of the isolation pattern, and, in the second direction, a width of the second region of the isolation pattern is greater than the width of the first region of the isolation pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more embodiments;

FIG. 2A is a cross-sectional view taken along line A-A′ of FIG. 1 according to one or more embodiments;

FIG. 2B is a cross-sectional view taken along line B-B′ of FIG. 1 according to one or more embodiments;

FIG. 2C is a cross-sectional view taken along line C-C′ of FIG. 1 according to one or more embodiments;

FIG. 3 is an enlarged view illustrating an example corresponding to area P1 of FIG. 2A according to one or more embodiments;

FIG. 4 is an enlarged view illustrating an example corresponding to area P1 of FIG. 2A according to one or more embodiments;

FIG. 5 is an enlarged view illustrating an example corresponding to area P1 of FIG. 2A according to one or more embodiments; and

FIGS. 6A to 10C are diagrams illustrating a method for manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

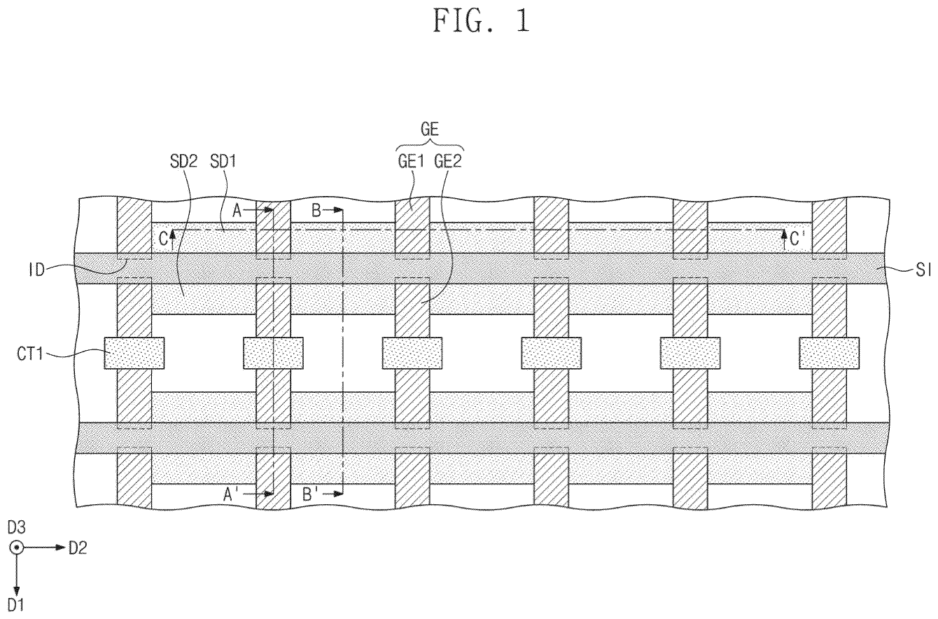

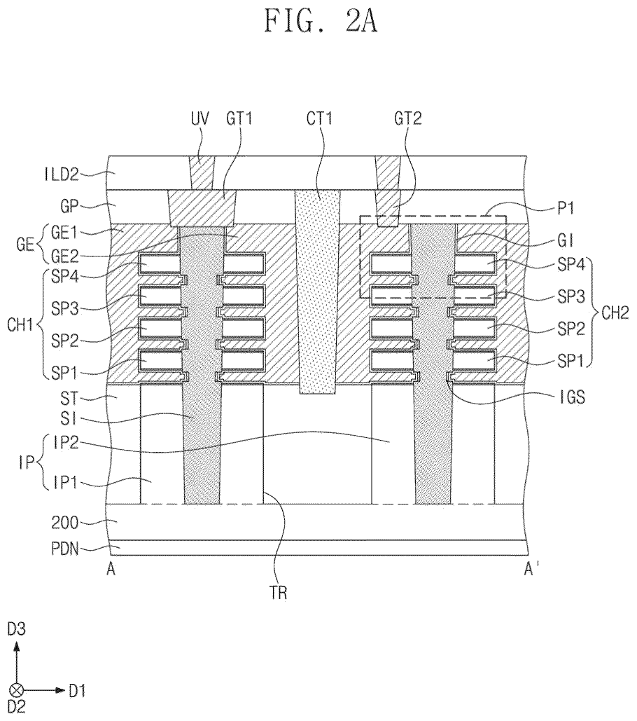

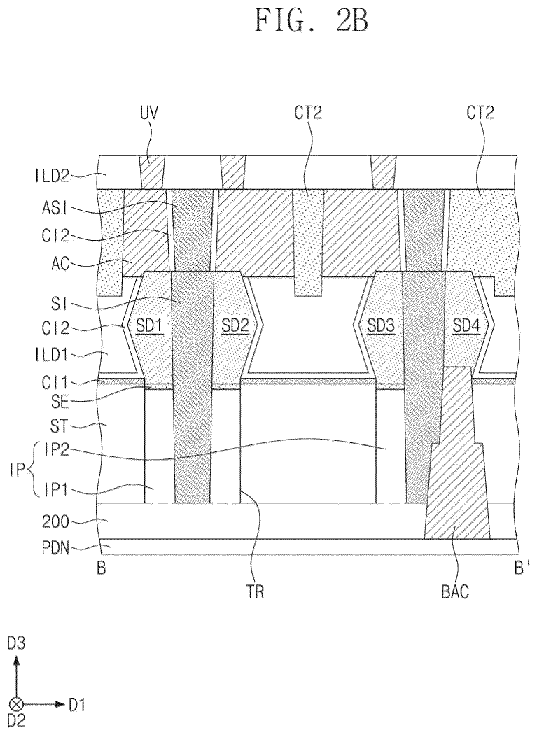

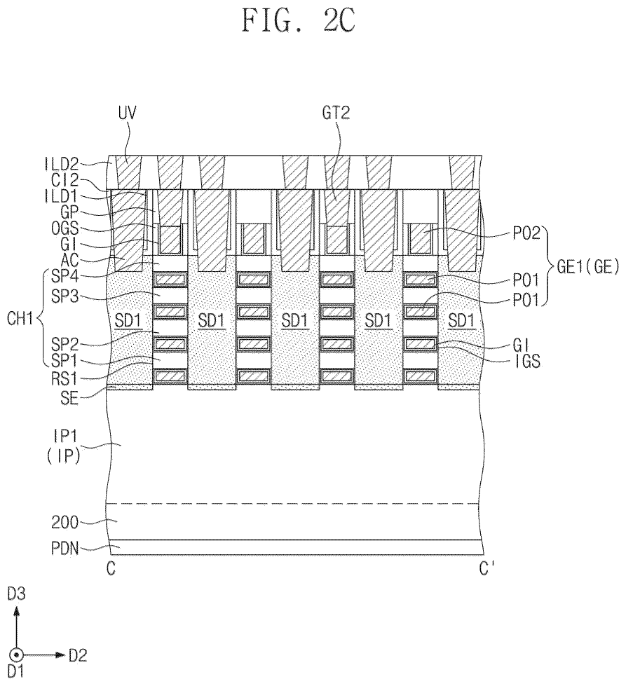

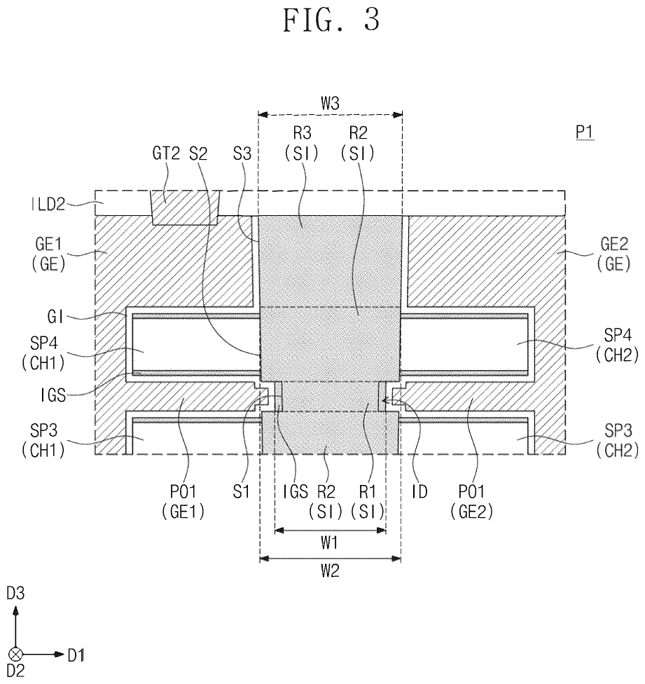

FIG. 1 is a plan view illustrating a semiconductor device according to one or more embodiments. FIG. 2A is a cross-sectional view taken along line A-A′ of FIG. 1 according to one or more embodiments. FIG. 2B is a cross-sectional view taken along line B-B′ of FIG. 1 according to one or more embodiments. FIG. 2C is a cross-sectional view taken along line C-C′ of FIG. 1 according to one or more embodiments. FIG. 3 is an enlarged view illustrating an example corresponding to area P1 of FIG. 2A according to one or more embodiments.

Referring to FIGS. 1 to 2C, a semiconductor device may include a substrate 200. Logic transistors constituting a logic circuit may be disposed on the substrate 200. For example, the substrate 200 may include a silicon-based insulating layer. In other words, the substrate 200 may be an insulating substrate. For example, the substrate 200 may include at least one of a silicon oxide (SiO₂) film, a silicon nitride (SiN) film, and a silicon oxynitride (SiON) film.

The substrate 200 may have a shape of a plate expanding along a plane defined by a first direction D1 and a second direction D2. The first direction D1 and the second direction D2 may be parallel to an upper surface of the substrate 200 and may intersect each other. For example, the first direction D1 and the second direction D2 may be perpendicular to each other.

An insulating pattern IP may be defined by a trench TR on the substrate 200. The insulating pattern IP may be a portion of the substrate 200. For example, the portion of the substrate 200 may extend in a third direction D3 perpendicular to the upper surface of the substrate 200. The semiconductor device may include a plurality of insulating patterns IP. The insulating patterns IP may be adjacent to each other in the first direction D1.

The insulating pattern IP may include a first insulating pattern IP1 and a second insulating pattern IP2 adjacent to each other in the first direction D1. The first and second insulating patterns IP1 and IP2 may each extend along the second direction D2. The first insulating pattern IP1 and the second insulating pattern IP2 may be spaced apart from each other in the first direction D1 by a device isolation pattern ST. The first insulating pattern IP1 and the second insulating pattern IP2 may be each penetrated by an isolation pattern SI.

The device isolation pattern ST may be provided on the substrate 200 and fill the trench TR. The device isolation pattern ST may surround the insulating pattern IP. The device isolation pattern ST may include an insulating material. For example, the device isolation pattern ST may include silicon oxide (SiO₂).

A first channel pattern CH1 and a second channel pattern CH2 may be provided on the insulating pattern IP. The first channel pattern CHI and the second channel pattern CH2 may be adjacent to each other in the first direction D1. The first channel pattern CHI and the second channel pattern CH2 may be spaced apart from each other in the first direction D1 with the isolation pattern SI therebetween.

The semiconductor device may include a plurality of first channel patterns CH1, and the plurality of first channel patterns CH1 may be spaced apart from each other in the second direction D2. The semiconductor device may include a plurality of second channel patterns CH2, and the plurality of second channel patterns CH2 may be spaced apart from each other in the second direction D2.

The first and second channel patterns CH1 and CH2 may each include a first semiconductor pattern SP1, a second semiconductor pattern SP2, a third semiconductor pattern SP3, and a fourth semiconductor pattern SP4 adjacent to each other in the third direction D3, but are not limited thereto. For example, the first and second channel patterns CH1 and CH2 may each include fewer or greater than four semiconductor patterns. For example, the first to fourth semiconductor patterns SP1, SP2, SP3, and SP4 may each include crystalline silicon.

First recesses RS1 may be defined between first channel patterns CH1 which are adjacent to each other in the second direction D2 and which are provided on the first insulating pattern IP1. Second recesses may be defined between second channel patterns CH2 which are adjacent to each other in the second direction D2 and which are provided on the first insulating pattern IP1. Third recesses may be defined between first channel patterns CH1 which are adjacent to each other in the second direction D2 and which are provided on the second insulating pattern IP2. Fourth recesses may be defined between second channel patterns CH2 which are adjacent to each other in the second direction D2 and which are provided on the second insulating pattern IP2.

A first source/drain pattern SD1 may be provided on the first insulating pattern IP1. The first source/drain pattern SD1 may fill the first recess RS1. The first source/drain pattern SD1 may be electrically connected to the first channel patterns CH1 on the first insulating pattern IP1.

A second source/drain pattern SD2 may be provided on the first insulating pattern IP1. The second source/drain pattern SD2 may fill the second recess. The second source/drain pattern SD2 may be electrically connected to the second channel patterns CH2 on the first insulating pattern IP1.

A third source/drain pattern SD3 may be provided on the second insulating pattern IP2. The third source/drain pattern SD3 may fill the third recess. The third source/drain pattern SD3 may be electrically connected to the first channel patterns CH1 on the second insulating pattern IP2.

A fourth source/drain pattern SD4 may be provided on the second insulating pattern IP2. The fourth source/drain pattern SD4 may fill the fourth recess. The fourth source/drain pattern SD4 may be electrically connected to the second channel patterns CH2 on the second insulating pattern IP2.

A seed pattern SE may be interposed between the first to fourth source/drain patterns SD1, SD2, SD3, and SD4 and the insulating pattern IP. The first to fourth source/drain patterns SD1, SD2, SD3, and SD4 may be epitaxial patterns which are formed through a selective epitaxial growth (SEG) process using the seed pattern SE as a seed. For example, the first to fourth source/drain patterns SD1, SD2, SD3, and SD4 may include silicon (Si) or silicon-germanium (SiGe).

The first to fourth source/drain patterns SD1, SD2, SD3, and SD4 may include impurity regions having a first conductive type (for example, a p-type) or a second conductive type (for example, an n-type). For example, the first and second source/drain patterns SD1 and SD2 may include impurity regions having the same conductive type, or may include impurity regions having different conductive types. For example, the third and fourth source/drain patterns SD3 and SD4 may include impurity regions having the same conductive type, or may include impurity regions having different conductive types.

A gate electrode GE may be provided on the first and second channel patterns CH1 and CH2. The gate electrode GE may surround and cover (e.g., laterally surround and vertically cover) each of the first and second channel patterns CH1 and CH2. The semiconductor device may include a plurality of gate electrodes GE. The gate electrodes GE may each extend along the first direction D1 and may be spaced apart from each other in the first direction D1 and the second direction D2.

The gate electrode GE may include an inner electrode PO1 and an outer electrode PO2. The inner electrode PO1 of the gate electrode GE may be provided between the uppermost semiconductor pattern SP4 among the plurality of semiconductor patterns SP1, SP2, SP3, and SP4 and the insulating pattern IP. The inner electrode PO1 of the gate electrode GE may be interposed between the plurality of semiconductor patterns SP1, SP2, SP3, and SP4. The outer electrode PO2 of the gate electrode GE may be provided on the uppermost semiconductor pattern SP4. For example, the inner electrode PO1 of the gate electrode GE may include four electrode parts, but is not limited thereto.

For example, the gate electrode GE may include at least one of a metal material (e.g., Ti, Mo, W, Cu, Al, Ta, Ru, Ir, Co, etc.), a metal nitride (e.g., a nitride of Ti, Mo, W, Cu, Al, Ta, Ru, Ir, Co, etc.), and poly silicon doped with impurities.

The gate electrode GE may include a first gate electrode GE1 surrounding the first channel pattern CHI and a second gate electrode GE2 surrounding the second channel pattern CH2. The first gate electrode GE1 may be spaced apart from the second gate electrode GE2 in the first direction D1 by the isolation pattern SI.

The isolation pattern SI may be provided on the substrate 200. The isolation pattern SI may penetrate each of the first insulating pattern IP1 and the second insulating pattern IP2. The isolation pattern SI may extend along the second direction D2 and the third direction D3. The semiconductor device may include a plurality of isolation patterns SI. The isolation patterns SI may be adjacent to each other in the first direction D1. For example, the isolation pattern SI may include an insulating material and may be a single film or a composite film.

The isolation pattern SI may be interposed between the first channel pattern CH1 and the second channel pattern CH2 so that the first channel pattern CH1 and the second channel pattern CH2 may be spaced apart from each other. The isolation pattern SI may contact one side surface of each of the semiconductor patterns SP1, SP2, SP3, and SP4 of the first channel pattern CH1 and contact one side surface of each of the semiconductor patterns SP1, SP2, SP3, and SP4 of the second channel pattern CH2. Accordingly, the first gate electrode GE1 may surround the other side surfaces not contacting the isolation pattern SI, upper surfaces, and lower surfaces of the semiconductor patterns SP1, SP2, SP3, and SP4. Likewise, the second gate electrode GE2 may surround the other side surfaces not contacting the isolation pattern SI, upper surfaces, and lower surfaces of the semiconductor patterns SP1, SP2, SP3, and SP4.

The isolation pattern SI may be interposed between the first source/drain pattern SD1 and the second source/drain pattern SD2 so that the first source/drain pattern SD1 and the second source/drain pattern SD2 may be spaced apart from each other. The isolation pattern SI may be interposed between the third source/drain pattern SD3 and the fourth source/drain pattern SD4 so that the third source/drain pattern SD3 and the fourth source/drain pattern SD4 may be spaced apart from each other. The isolation pattern SI may contact one side surface of each of the first to fourth source/drain patterns SD1, SD2, SD3, and SD4. The isolation pattern SI may be interposed between the first gate electrode GE1 and the second gate electrode GE2 so that the first gate electrode GE1 and the second gate electrode GE2 may be spaced apart from each other.

An inner gate spacer IGS may be interposed between the inner electrode PO1 of the gate electrode GE and the first to fourth source/drain patterns SD1, SD2, SD3, and SD4. For example, the inner gate spacer IGS may include at least one of SiO₂ and a low-k material. The low-k material may be defined as a material having a lower dielectric constant than silicon oxide. As the inner gate spacer IGS is provided, a distance between the inner electrode PO1 of the gate electrode GE and the first to fourth source/drain patterns SD1, SD2, SD3, and SD4 may increase. As a result, unnecessary capacitance between the inner electrode PO1 of the gate electrode GE and the first to fourth source/drain patterns SD1, SD2, SD3, and SD4 may be reduced. Thus, electrical characteristics of the semiconductor device may be improved.

The inner gate spacer IGS may be interposed between the first gate electrode GE1 and the first channel pattern CH1, and between the second gate electrode GE2 and the second channel pattern CH2. The inner gate spacer IGS may cover a lower surface and an upper surface of each of the semiconductor patterns SP1, SP2, SP3, and SP4. The inner gate spacer IGS may be interposed between the upper surface of each of the semiconductor patterns SP1, SP2, SP3, and SP4 and a gate dielectric pattern GI, and between the lower surface of each of the semiconductor patterns SP1, SP2, SP3, and SP4 and the gate dielectric pattern GI. The inner gate spacer IGS may surround and cover the inner electrode PO1 of the gate electrode GE. The inner gate spacer IGS may partially cover a side surface of the isolation pattern SI.

The gate dielectric pattern GI may be interposed between the gate electrode GE and the semiconductor patterns SP1, SP2, SP3, and SP4 (e.g., between gate electrodes GE1/GE2 and respective semiconductor patterns). The gate dielectric pattern GI may cover an upper surface, a lower surface, and one side surface of each the semiconductor patterns SP1, SP2, SP3, and SP4 and the gate electrode GE. The gate dielectric pattern GI may partially cover the side surface of the isolation pattern SI. The gate dielectric pattern GI may cover an upper surface of the device isolation pattern ST under the gate electrode GE. The gate dielectric pattern GI may be interposed between the outer electrode PO2 of the gate electrode GE and an outer gate spacer OGS.

For example, the gate dielectric pattern GI may include at least one of silicon oxide (SiO₂), silicon oxynitride (SiON), and a material having a high dielectric constant. The material having a high dielectric constant may be defined as a material having a higher dielectric constant than silicon oxide.

Referring to FIG. 3, the isolation pattern SI may include a first region R1 in which side surfaces of the isolation pattern SI (e.g., side surfaces opposite each other in the direction D1) are indented, a second region R2 contacting each of the first channel pattern CH1 and the second channel pattern CH2, and a third region R3 at a higher level than the fourth semiconductor pattern SP4. The third region R3 of the isolation pattern SI may extend in a horizontal direction at a greater distance as compared to the first region R1.

With respect to the first direction D1, the first region R1 of the isolation pattern SI may have a first width W1, the second region R2 of the isolation pattern SI may have a second width W2, and the third region R3 of the isolation pattern SI may have a third width W3. The first width W1 may be smaller than the second and third widths W2 and W3. The third width W3 may be substantially the same as or greater than the second width W2.

The first region R1 of the isolation pattern SI may have a first side surface S1. The second region R2 of the isolation pattern SI may have a second side surface S2. The third region R3 of the isolation pattern SI may have a third side surface S3.

For example, the first side surface S1 may have a linear profile. For another example, the first side surface S1 may have a profile concave toward the inside of the first region R1.

The third side surface S3 and the second side surface S2 may be continuously connected (e.g., the sides may be continuous). The third side surface S3 and the second side surface S2 being continuously connected may indicate that the third side surface S3 and the second side surface S2 are connected to each other not passing through an additional surface (e.g., an upper surface of the second region R2) between the third side surface S3 and the second side surface S2. The first side surface S1 and the second side surface S2 may be connected to each other through a lower surface of the second region R2 of the isolation pattern SI. The second side surface S2 may extend in the first direction DI or an opposite direction of the first direction D1 from the first side surface S1.

Indent regions ID may be formed on side surfaces of the first region R1 (e.g., side surfaces opposite each other in the direction D1). The inner gate spacer IGS and the gate dielectric pattern GI may be provided in the indent region ID. Inner gate spacers IGS and gate dielectric patterns GI may be respectively sequentially provided on side surfaces of the isolation pattern SI in the first region R1 (e.g., side surfaces opposite each other in the direction D1). That is, the inner gate spaces IGS may be provided on the side surfaces of the isolation pattern SI in the first region R1, and the gate dielectric patterns GI may be provided on side surfaces of the inner gate spacers IGS that are provided on side surfaces of the isolation pattern SI in first region R1. The inner gate spacers IGS may respectively contact side surfaces of the first region R1 of the isolation pattern SI. The first region R1 of the isolation pattern SI may be spaced apart from the gate dielectric pattern GI by the inner gate spacer IGS.

According to one or more embodiments, side surfaces of the first region R1 of the isolation pattern SI may be indented (e.g., side surfaces opposite each other in the direction D1). The inner gate spacer IGS and the gate dielectric pattern GI may be provided in the indent region ID. Accordingly, an overlap region between the inner electrode PO1 of the first gate electrode GE1 and the first channel pattern CH1 and an overlap region between the inner electrode PO1 of the second gate electrode GE2 and the second channel pattern CH2 may increase. As a result, electrical characteristics of the semiconductor device may be improved.

Referring to FIGS. 1 to 2C, outer gate spacers OGS may be provided on side surfaces of the outer electrode PO2 of the gate electrode GE. The outer gate spacer OGS may include a single film or a composite film. For example, the outer gate spacer OGS may include at least one of SiON, SiCN, SiOCN, and SiN.

A gate capping pattern GP may be provided on an upper surface of the outer electrode PO2 of the gate electrode GE. For example, the gate capping pattern GP may include at least one of SiON, SiCN, SiOCN, and SiN.

A first interlayer insulating film ILD1 may be provided on the substrate 200. The first interlayer insulating film ILD1 may cover the outer gate spacers OGS and the first to fourth source/drain patterns SD1, SD2, SD3, and SD4. An upper surface of the first interlayer insulating film ILD1 may be placed at the substantially same level as an upper surface of the gate capping pattern GP. For example, the first interlayer insulating film ILD1 may include an insulating material.

An active contact AC may penetrate the first interlayer insulating film ILD1 along the third direction D3. The semiconductor device may include a plurality of active contacts AC, and a lower portion of each of active contacts AC may be buried in an upper portion of at least one of the first, second, third, and fourth source/drain pattern SD1, SD2, SD3, and SD4. An additional isolation pattern ASI including an insulating material may be interposed between the active contacts AC, and accordingly, the active contacts AC may be spaced apart from each other.

For example, the active contact AC may include at least one of a metal material (e.g., Ti, Mo, W, Cu, Al, Ta, Ru, Ir, Co, etc.) and a metal nitride (e.g., a nitride of Ti, Mo, W, Cu, Al, Ta, Ru, Ir, Co, etc.). In addition, a silicide pattern may be interposed between the active contact AC and the first to fourth source/drain patterns SD1, SD2, SD3, and SD4. Accordingly, contact resistance between the active contact AC and the first to fourth source/drain patterns SD1, SD2, SD3, and SD4 may be improved. For example, the silicide pattern may include a metal silicide (e.g., a silicide of Ti, Mo, W, Cu, Al, Ta, Ru, Ir, etc.).

A first gate contact GT1 and a second gate contact GT2 may penetrate the gate capping pattern GP and may contact the gate electrode GE. The first gate contact GT1 and the second gate contact GT2 may each include at least one of a metal material (e.g., Ti, Mo, W, Cu, Al, Ta, Ru, Ir, Co, etc.) and a metal nitride (e.g., a nitride of Ti, Mo, W, Cu, Al, Ta, Ru, Ir, Co, etc.) Accordingly, the first gate contact GT1 and the second gate contact GT2 may be electrically connected to the gate electrode GE. The first gate contact GT1 may contact each of the first gate electrode GE1 and the second gate electrode GE2. The second gate contact GT2 may contact the first gate electrode GEL or the second gate electrode GE2.

A first capping insulating film CI1 may cover an upper surface of the device isolation pattern ST. For example, the first capping insulating film CI1 may include an insulating material.

A second capping insulating film CI2 may cover a side surface of the first to fourth source/drain patterns SD1, SD2, SD3, and SD4. The second capping insulating film CI2 may be interposed between the first interlayer insulating film ILD1 and the first to fourth source/drain patterns SD1, SD2, SD3, and SD4. The second capping insulating film CI2 may be interposed between the active contacts AC and the additional isolation pattern ASI. For example, the second capping insulating film CI2 may include an insulating material.

A first cutting pattern CT1 may be interposed between the gate electrodes GE. The gate electrodes GE may be spaced apart from each other in the first direction D1 by the first cutting pattern CT1. For example, the first cutting pattern CT1 may include an insulating material.

A second cutting pattern CT2 may be interposed between the active contacts AC. The active contacts AC may be spaced apart from each other in the first direction D1 by the second cutting pattern CT2. For example, the second cutting pattern CT2 may include an insulating material.

A second interlayer insulating film ILD2 may be provided on the first interlayer insulating film ILD1. The second interlayer insulating film ILD2 may be formed on the active contacts AC and the gate capping pattern GP. For example, the second interlayer insulating film ILD2 may include an insulating material.

Upper vias UV may penetrate the second interlayer insulating film ILD2 and may contact the active contacts AC, the first gate contact GT1, and the second gate contact GT2. For example, the upper vias UV may each include a metal material (e.g., Ti, Mo, W, Cu, Al, Ta, Ru, Ir, Co, etc.), and accordingly, may be electrically connected to the active contacts AC, the first gate contact GT1, and the second gate contact GT2.

For example, a plurality of metal patterns and via patterns may be provided on the upper vias UV. Each of the metal patterns and the via patterns may be alternately stacked along the third direction D3. The metal patterns and the via patterns may each include a metal material (e.g., Ti, Mo, W, Cu, Al, Ta, Ru, Ir, Co, etc.).

A power transmission network layer PDN may be provided on a lower surface of the substrate 200. A rear surface conductive contact BAC may be interposed between the power transmission network layer PDN and at least one of the first, second, third, or fourth source/drain pattern SD1, SD2, SD3, or SD4. The rear surface conductive contact BAC may be interposed between the fourth source/drain pattern SD4 and the power transmission network layer PDN, but embodiments are not limited thereto. The rear surface conductive contact BAC may include at least one of a metal material (e.g., Ti, Mo, W, Cu, Al, Ta, Ru, Ir, Co, etc.) and a metal nitride (e.g., a nitride of Ti, Mo, W, Cu, Al, Ta, Ru, Ir, Co, etc.).

The power transmission network layer PDN may include a plurality of lower lines electrically connected to at least one of the first, second, third, and fourth source/drain pattern SD1, SD2, SD3, and SD4 through the rear surface conductive contact BAC. For example, the power transmission network layer PDN may include a line network for applying a source voltage. For example, the power transmission network layer PDN may include a line network for applying a drain voltage.

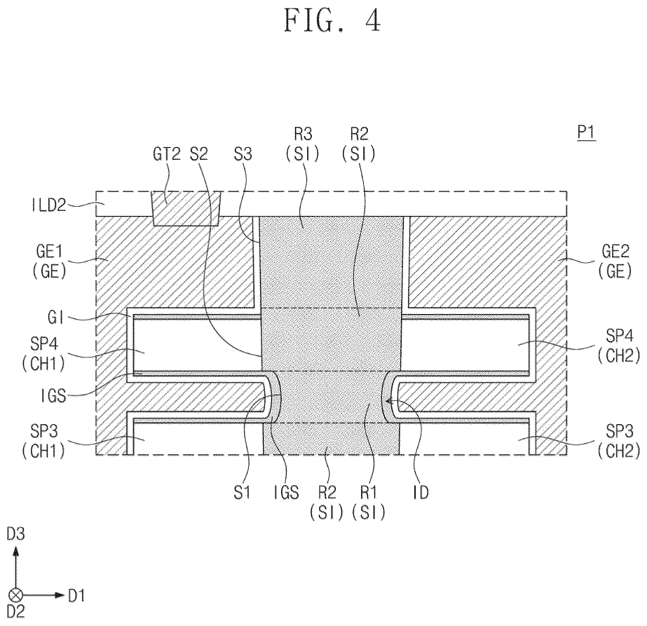

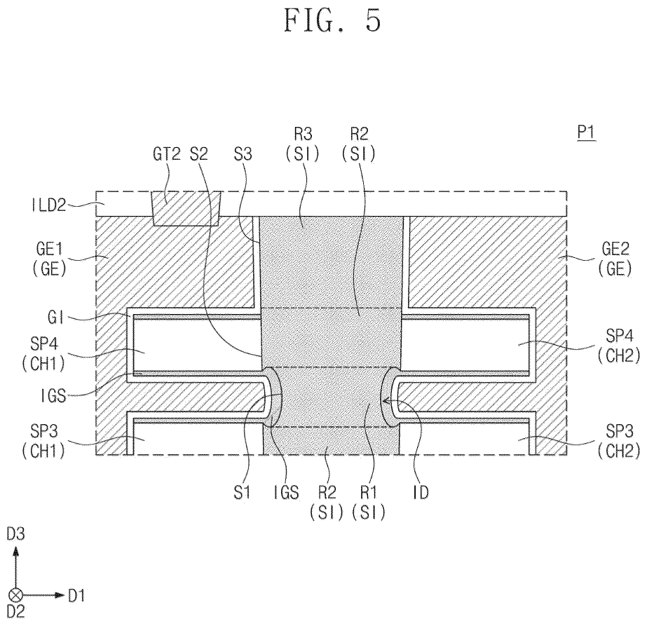

FIG. 4 is an enlarged view illustrating an example corresponding to area P1 of FIG. 2A according to one or more embodiments. FIG. 5 is an enlarged view illustrating an example corresponding to area P1 of FIG. 2A according to one or more embodiments. Description of aspects the same as or similar to those described above may be omitted.

During an indent process for an isolation pattern SI, forms of the isolation pattern SI and surrounding components may be changed according to a condition of the indent process. FIGS. 4 and 5 show examples of embodiments of a semiconductor device according to a condition of the indent process for the isolation pattern SI.

Referring to FIG. 4, a first side surface S1 of an isolation pattern SI may have a profile concave toward the inside of the isolation pattern SI. A portion of a gate dielectric pattern GI and a portion of an inner gate spacer IGS may be concave toward the inside of a first region R1 of the isolation pattern SI.

A portion of the inner gate spacer IGS in an indent region ID may be connected to another portion of the inner gate spacer IGS contacting first to fourth semiconductor patterns SP1, SP2, SP3, and SP4.

The first side surface S1 of the first region R1 of the isolation pattern SI may be continuously connected to a second side surface S2 of a second region R2.

Referring to FIG. 5, a height of an indent region ID may be greater than a distance between a pair of semiconductor patterns adjacent to each other among first to fourth semiconductor patterns SP1, SP2, SP3, and SP4. An inner gate spacer IGS in the indent region ID may protrude into a second region R2 of an isolation pattern SI. A height of a portion of the inner gate spacer IGS in the indent region ID may be greater than the distance between the pair of semiconductor patterns adjacent to each other among the first to fourth semiconductor patterns SP1, SP2, SP3, and SP4.

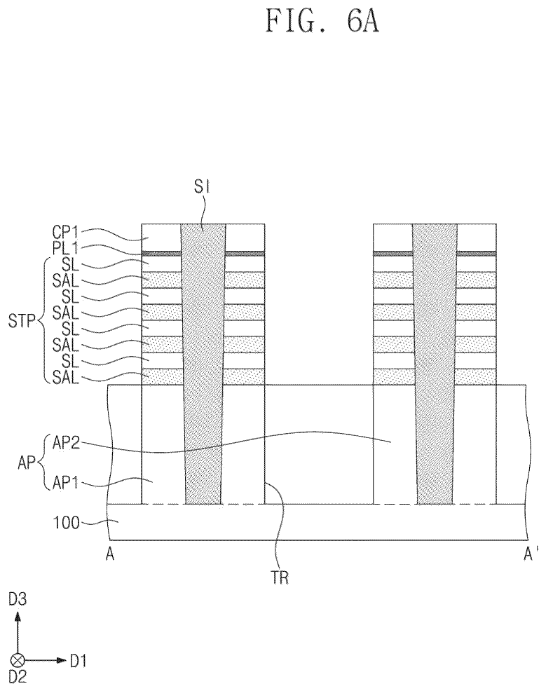

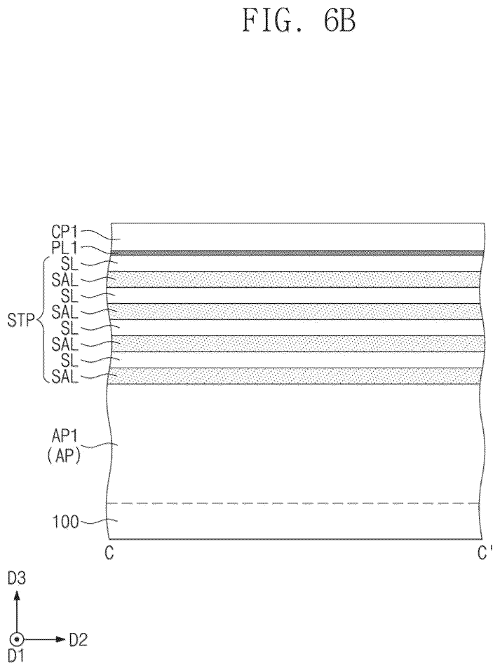

Hereinafter, a method for manufacturing a semiconductor device according to one or more embodiments will be described with reference to FIGS. 6A to 10C. Description of aspects the same as or similar to those described above may be omitted.

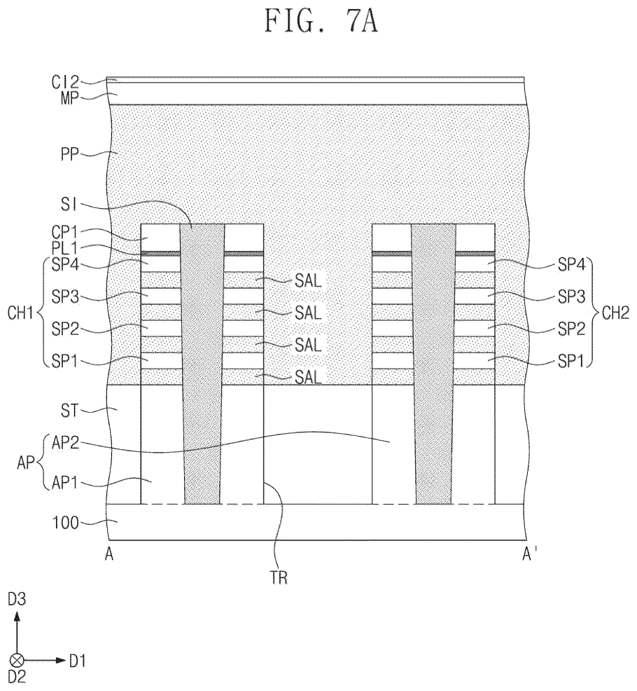

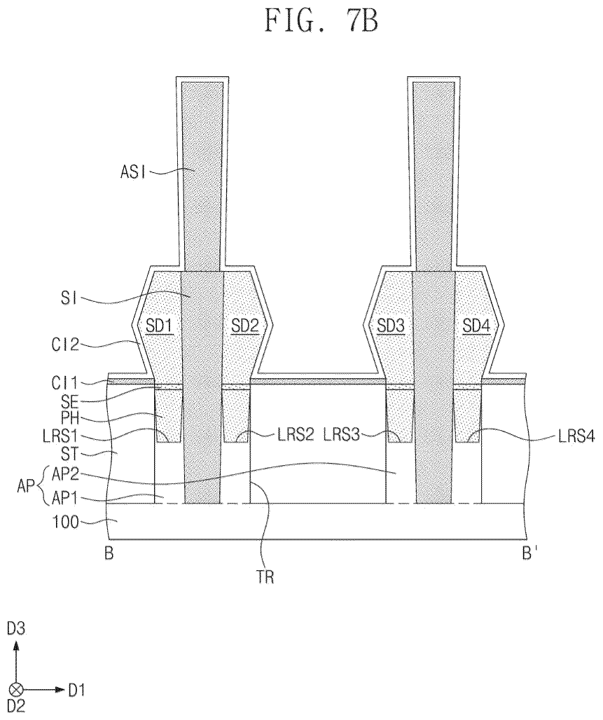

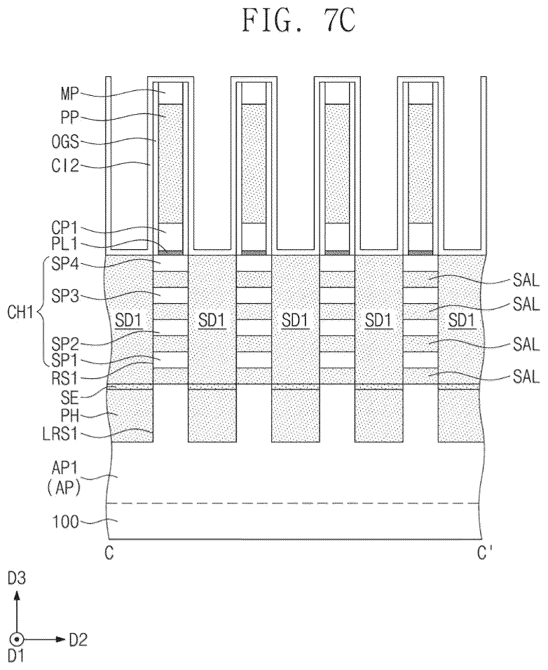

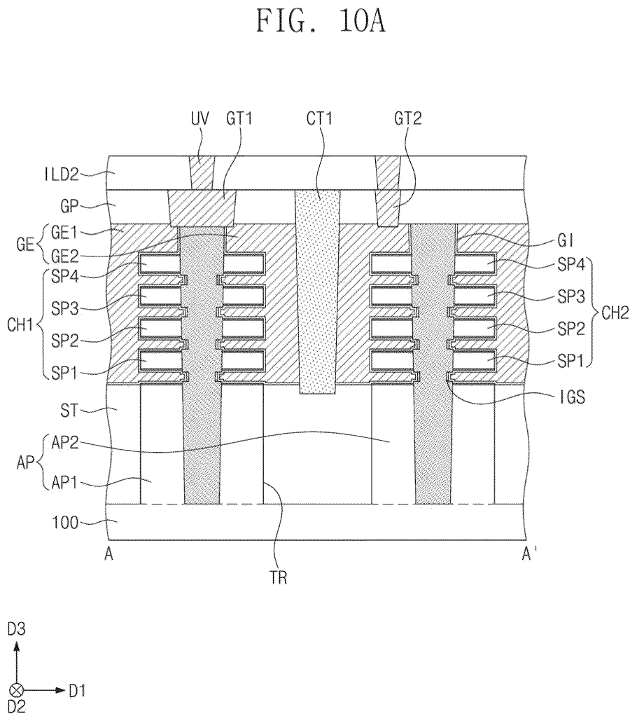

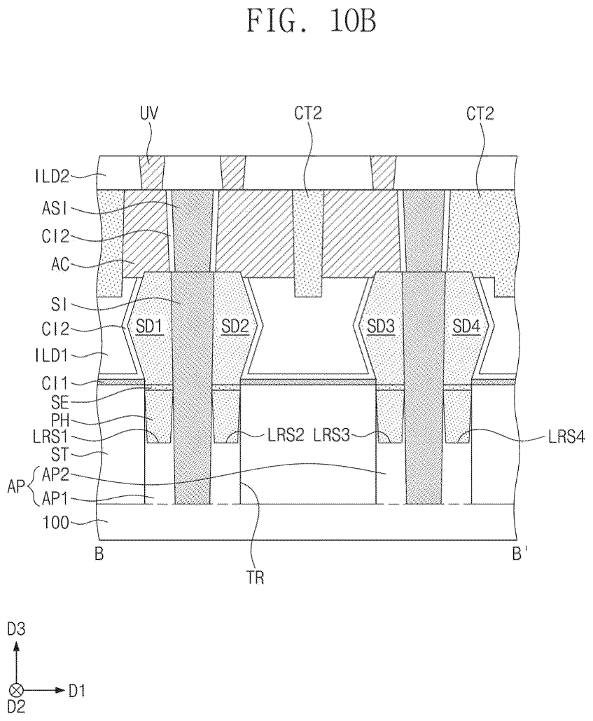

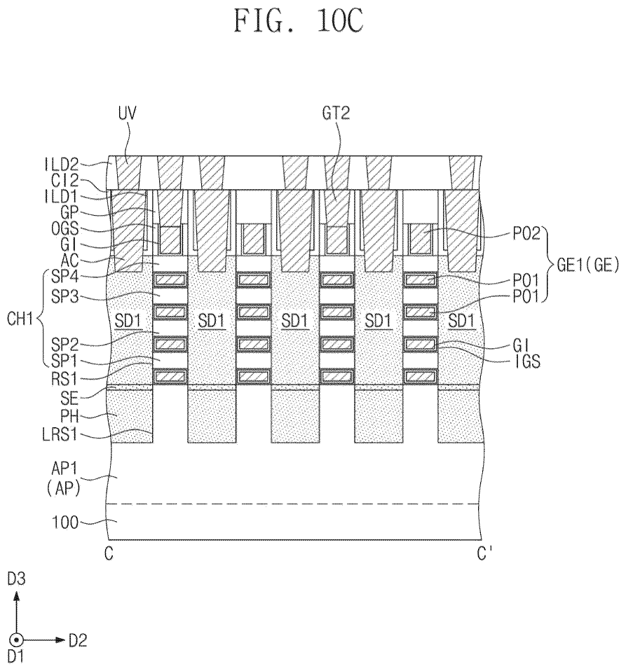

FIGS. 6A to 10C are diagrams illustrating a method for manufacturing a semiconductor device according to one or more embodiments. More specifically, FIGS. 6A, 7A, 8A, 9A, and 10A are each a cross-sectional view taken along line A-A′ of FIG. 1. FIGS. 7B and 10B are each a cross-sectional view taken along line B-B′ of FIG. 1. FIGS. 6B, 7C, 8B, 9B, and 10C are each a cross-sectional view taken along line C-C′ of FIG. 1.

Referring to FIGS. 1, 6A, and 6B, a semiconductor substrate 100 may be provided. For example, the semiconductor substrate 100 may be a semiconductor substrate including a semiconductor material, such as a single-crystalline silicon substrate, a silicon-germanium substrate, and an SOI substrate. Stack patterns STP, first protective films PL1, and first capping patterns CP1 may be sequentially formed on the semiconductor substrate 100. For example, forming the stack patterns STP, the first protective films PL1, and the first capping patterns CP1 may include alternately stacking semiconductor layers SL and sacrificial layers SAL on the semiconductor substrate 100 and then sequentially stacking the first protective film PL1 and the first capping pattern CP1, forming mask patterns extending in the first direction D1, and performing a patterning process using the mask patterns as an etching mask. During the patterning process, the semiconductor substrate 100 may be partially removed together, and trenches TR which define a first active pattern AP1 and a second active pattern AP2 may be formed. The first and second active patterns AP1 and AP2 may extend along the second direction D2.

An isolation pattern SI may be formed to penetrate each of the stack patterns STP, the first protective film PL1, and the first capping pattern CP1. Device isolation patterns ST may be formed to fill the trenches TR.

The sacrificial layers SAL may include a material capable of having an etching selectivity with the semiconductor layers SL. Accordingly, when a process of removing the sacrificial layers SAL to be described later is performed, the semiconductor layers SL may not be removed or may be slightly removed even if the sacrificial layers SAL are removed. For example, the semiconductor layers SL may include one among silicon (Si), germanium (Ge), and silicon-germanium (SiGe), and the sacrificial layers SAL may include one among silicon (Si), germanium (Ge), and silicon-germanium (SiGe) that is different from the material of the semiconductor layers SL.

The first protective films PL1 may include an insulating material, and the first capping patterns CP1 may include silicon-germanium (SiGe).

For example, an additional insulating film may be formed to cover side surfaces of each of the stack patterns STP, the first protective films PL1, and the first capping patterns CP1.

Referring to FIGS. 1, 7A to 7C, sacrificial patterns PP may be formed to each extend along the first direction D1 on the semiconductor substrate 100. The sacrificial patterns PP may be formed to cover upper surfaces of the device isolation patterns ST, side surfaces of each of the stack patterns STP, the first protective films PL1, and the first capping patterns CP1, and upper surfaces of the first capping patterns CP1. Hard mask patterns MP may be formed on upper surfaces of the sacrificial patterns PP. For example, the sacrificial pattern PP may include polysilicon. Then, outer gate spacers OGS may be respectively formed on side surfaces of the sacrificial patterns PP.

First recesses RS1 may be formed in the stack pattern STP on the first active pattern AP1 contacting one side surface of the isolation pattern SI. Second recesses may be formed in the stack pattern STP on the first active pattern AP1 contacting another side surface of the isolation pattern SI. Third recesses may be formed in the stack pattern STP on the second active pattern AP2 contacting one side surface of the isolation pattern SI. Fourth recesses may be formed in the stack pattern STP on the second active pattern AP2 contacting another side surface of the isolation pattern SI. For example, the first recess RS1 to the fourth recess may be formed by partially removing the stack pattern STP using the hard mask patterns MP as an etching mask.

The semiconductor layers SL may be divided into first channel patterns CH1 spaced apart from each other in the second direction D2 by the first recesses RS1 and the third recesses, and may be divided into second channel patterns CH2 spaced apart from each other in the second direction D2 by the second recesses and the fourth recesses.

During the removing process, an additional insulating film and the outer gate spacer OGS which cover side surfaces of each of first to fourth semiconductor patterns SP1, SP2, SP3, and SP4, the sacrificial layers SAL, the first protective films PL1, and the first capping patterns CP1 may be removed together. A remaining portion of each of the additional insulating film and the outer gate spacer OGS may partially constitute a first capping insulating film CI1.

A first lower recess LRS1 may be formed under the first recess RS1. A second lower recess LRS2 may be formed under the second recess. A third lower recess LRS3 may be formed under the third recess. A fourth lower recess LRS4 may be formed under the fourth recess.

Sacrificial contact patterns PH may be formed to fill the inside of the first to fourth lower recesses LRS1, LRS2, LRS3, and LRS4 through an SEG process using the semiconductor substrate 100 as a seed. For example, the sacrificial contact patterns PH may include silicon-germanium (SiGe). Then, seed patterns SE may be formed on the sacrificial contact patterns PH. Additional isolation patterns ASI may be formed on isolation patterns SI.

First source/drain patterns SD1 may be formed in the first recesses RS1. Second source/drain patterns SD2 may be formed in the second recesses. Third source/drain patterns SD3 may be formed in the third recesses. Fourth source/drain patterns SD4 may be formed in the fourth recesses. The first to fourth source/drain patterns SD1, SD2, SD3, and SD4 may be formed through a SEG process using the seed patterns SE as a seed.

A second capping insulating film CI2 may be formed to cover the first to fourth source/drain patterns SD1, SD2, SD3, and SD4 and the additional isolation patterns ASI.

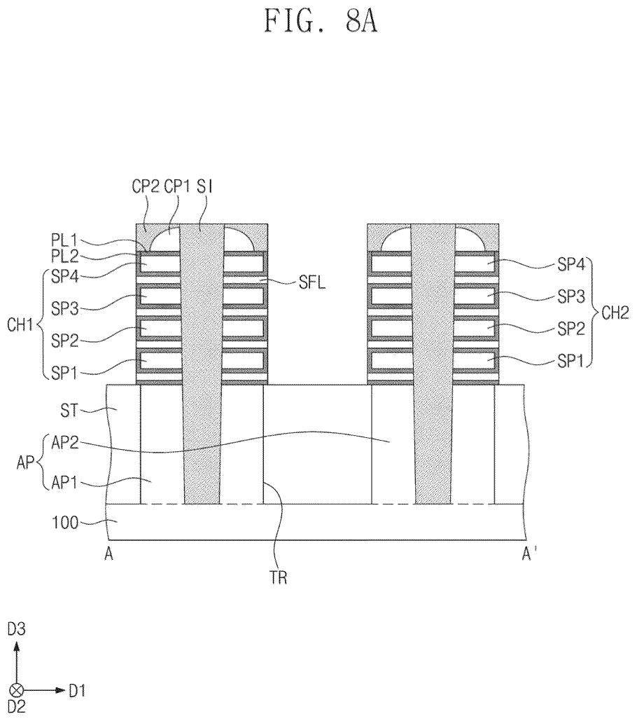

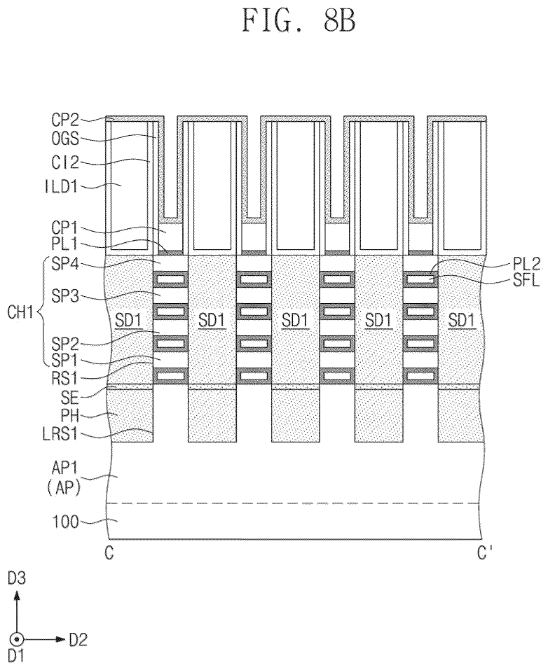

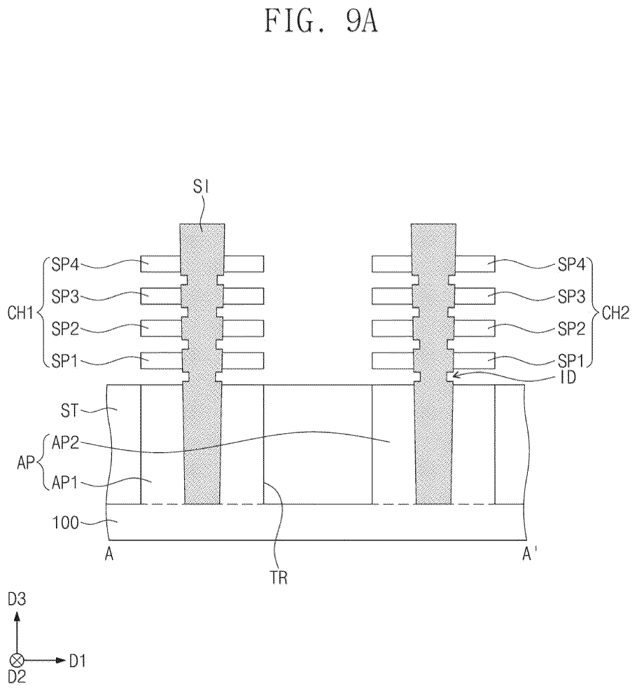

Referring to FIGS. 1, 8A, and 8B, a first interlayer insulating film ILD1 may be formed to cover the first to fourth source/drain patterns SD1, SD2, SD3, and SD4, the hard mask patterns MP, and the outer gate spacers OGS. Then, the first interlayer insulating film ILD1 on upper surfaces of the sacrificial patterns PP may be removed. During the removing process, the hard mask patterns MP may be removed together, and the sacrificial patterns PP may be exposed.

Thereafter, the exposed sacrificial patterns PP may be removed, and the first capping pattern CP1 may be exposed to the outside. The additional insulating film which covers the side surfaces of each of the first to fourth semiconductor patterns SP1, SP2, SP3, and SP4, the sacrificial layers SAL, the first protective films PL1, and the first capping patterns CP1 may be removed. Accordingly, the side surfaces of each of the semiconductor patterns SP1, SP2, SP3, and SP4, the sacrificial layers SAL, the first protective films PL1, and the first capping patterns CP1 may be exposed to the outside.

Thereafter, the exposed sacrificial layers SAL may be selectively removed. The first to fourth semiconductor patterns SP1, SP2, SP3, and SP4 may not be removed or may be slightly removed due to high etching selectivity of the sacrificial layers SAL.

Second protective films PL2 may be formed to surround the first to fourth semiconductor patterns SP1, SP2, SP3, and SP4. The second protective films PL2 may include an insulating material. A sacrificial filling pattern SFL may be formed to fill regions in which the sacrificial layers SAL are removed. A second capping pattern CP2 may be formed to cover the first capping pattern CP1. The second capping pattern CP2 may be formed to cover an upper surface of the fourth semiconductor pattern SP4. The second capping pattern CP2 may include an insulating material.

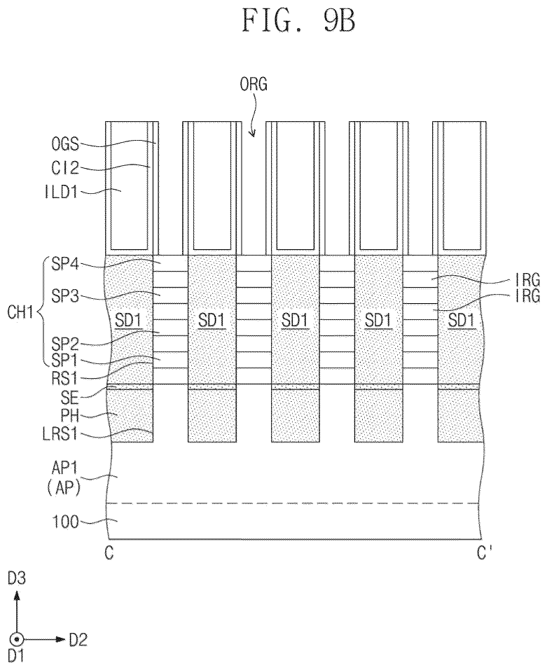

Referring to FIGS. 1, 9A, and 9B, sacrificial filling patterns SFL may be removed on the semiconductor substrate 100. Accordingly, a portion of side surfaces of the isolation patterns SI may be exposed to the outside.

A removing process for the portion of the side surfaces of the isolation patterns SI may be performed, and accordingly, indent regions ID may be formed on the side surfaces of the isolation patterns SI. During the removing process, second capping patterns CP2 may be removed together. Thereafter, the first and second protective films PL1 and PL2 and the first capping patterns CP1 may be removed on the semiconductor substrate 100.

According to one or more embodiments, during the removing process, an upper portion of the isolation pattern SI (in other words, the third region R3 of FIG. 3) surrounded by the first and second capping patterns CP1 and CP2 may not be removed. Accordingly, as described with reference to FIG. 3, the third width W3 of the third region R3 may be greater than the first width W1 of the first region R1 of which side surfaces are indented (e.g., side surfaces opposite each other in the direction D1). Since the upper portion of the isolation pattern SI (i.e., the third region R3 of FIG. 3) may have a sufficient width, a sufficient distance between a first gate electrode GE1 and a second gate electrode GE2 may be ensured. In addition, since the upper portion of the isolation pattern SI (i.e., the third region R3 of FIG. 3) may have a sufficient height, unnecessary contact between first and second gate contacts GT1 and GT2 and the fourth semiconductor pattern SP4 may be prevented during a process of forming the first and second gate contacts GT1 and GT2. Thus, process defects of the semiconductor device may be reduced, and productivity of the semiconductor device may be improved.

An outer region ORG may be formed in a region in which the first protective films PL1 and the first capping patterns CP1 are removed. An inner region IRG may be formed in a region in which the second protective films PL2 and the sacrificial filling patterns SPF are removed.

Referring to FIGS. 1, 10A to 10C, an inner gate spacer IGS may be formed on the first to fourth source/drain patterns SD1, SD2, SD3, and SD4. A gate dielectric pattern GI may be formed on the first to fourth semiconductor patterns SP1, SP2, SP3, and SP4. A first gate electrode GE1 may be formed to surround the first channel patterns CH1. A second gate electrode GE2 may be formed to surround the second channel patterns CH2. The first and second gate electrodes GE1 and GE2 may constitute a gate electrode GE.

According to one or more embodiments, a process of forming the inner gate spacer IGS may be performed after an indent process for the isolation pattern SI. Accordingly, the inner gate spacer IGS may not be unnecessarily removed by the indent process for the isolation pattern SI. As a result, the inner gate spacer IGS may have a sufficient thickness, and as described above, unnecessary capacitance between an inner electrode PO1 of the gate electrode GE and the first to fourth source/drain patterns SD1, SD2, SD3, and SD4 may be reduced. Thus, electrical characteristics of the semiconductor device may be improved.

A gate capping pattern GP may be formed to cover an upper surface of the gate electrode GE. A first cutting pattern CT1 may be formed to penetrate the gate electrode GE.

Active contacts AC may be formed to penetrate the first interlayer insulating film ILD1 and contact at least one of the first, second, third, and fourth source/drain pattern SD1, SD2, SD3, and SD4. A second cutting pattern CT2 may be formed to penetrate the active contact AC.

A first gate contact GT1 may be formed to penetrate the gate capping pattern GP and contact the first gate electrode GE1 and the second gate electrode GE2. A second gate contact GT2 may be formed to penetrate the gate capping pattern GP and contact the first gate electrode GE1 or the second gate electrode GE2.

A second interlayer insulating film ILD2 may be formed on the first interlayer insulating film ILD1. Upper vias UV may be formed to penetrate the second interlayer insulating film ILD2 and contact the active contacts AC and the first and second gate contacts GT1 and GT2. Metal patterns and via patterns may be formed on the second interlayer insulating film ILD2.

Referring back to FIGS. 1 to 2C, the semiconductor substrate 100 may be turned over so that a rear surface of the semiconductor substrate 100 is exposed. The exposed semiconductor substrate 100 may be selectively removed. Accordingly, a portion of the isolation pattern SI, the sacrificial contact patterns PH, and the device isolation pattern ST may be exposed to the outside.

A substrate 200 may be formed in a region in which the semiconductor substrate 100 is removed. A rear surface conductive contact BAC may be formed to penetrate the substrate 200 and contact at least one of the first, second, third, and fourth source/drain pattern SD1, SD2, SD3, and SD4.

Thereafter, a power transmission network layer PDN may be formed on a lower surface of the substrate 200.

According to one or more embodiments, side surfaces of a first region of an isolation pattern may be indented. An inner gate spacer and a gate dielectric pattern may be provided in an indent region. Accordingly, an overlap region between an inner electrode of a first gate electrode and a first channel pattern and an overlap region between an inner electrode of a second gate electrode and a second channel pattern may increase. As a result, electrical characteristics of a semiconductor device may be improved.

According to one or more embodiments, during an indent process for side surfaces of a first region of an isolation pattern, an upper portion of the isolation pattern (in other words, the third region of FIG. 3) surrounded by first and second capping patterns may not be removed. Accordingly, a width of the upper portion of the isolation pattern (i.e., the third width of FIG. 3) may be greater than a first width of the first region of which side surfaces are indented. Since the upper portion of the isolation pattern has a sufficient width, a sufficient distance between a first gate electrode and a second gate electrode may be ensured. In addition, since the upper portion of the isolation pattern has a sufficient height, unnecessary contact between first and second gate contacts and a fourth semiconductor pattern may be prevented during a process of forming the first and second gate contacts. Thus, a process defects of the semiconductor device may be reduced, and productivity of the semiconductor device may be improved.

According to one or more embodiments, a process of forming an inner gate spacer may be performed after an indent process for an isolation pattern. Accordingly, the inner gate spacer may not be unnecessarily removed by the indent process for the isolation pattern. As a result, the inner gate spacer may have a sufficient thickness, and unnecessary capacitance between an inner electrode of a gate electrode and first to fourth source/drain patterns may be reduced. Thus, electrical characteristics of the semiconductor device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a first channel pattern and a second channel pattern on a substrate, wherein the first channel pattern comprises a plurality of first semiconductor patterns spaced apart in a first direction that is perpendicular to an upper surface of the substrate, and wherein the second channel pattern comprises a plurality of second semiconductor patterns spaced apart in the first direction; and
an isolation pattern between the first channel pattern and the second channel pattern,
wherein the isolation pattern comprises
a first region,
a second region contacting each of the first channel pattern and the second channel pattern, and
a third region at a level that is higher than an uppermost first semiconductor pattern among the plurality of first semiconductor patterns and an uppermost second semiconductor pattern among the plurality of second semiconductor patterns,
wherein, in a second direction parallel to the upper surface of the substrate, a width of the third region of the isolation pattern is greater than a width of the first region of the isolation pattern, and
wherein, in the second direction, a width of the second region of the isolation pattern is greater than the width of the first region of the isolation pattern.

2. The semiconductor device of claim 1, wherein, in the second direction, the width of the third region of the isolation pattern is substantially equal to or greater than a width of the second region of the isolation pattern.

3. The semiconductor device of claim 1, wherein side surfaces of the third region of the isolation pattern extend in the second direction at a greater distance than side surfaces of the first region of the isolation pattern.

4. The semiconductor device of claim 1, wherein, in the second direction, the width of the first region of the isolation pattern is smaller than a width of the second region of the isolation pattern.

5. The semiconductor device of claim 1, wherein side surfaces of the first region opposite each other in the second direction of the isolation pattern are concave toward an inside of the first region in the second direction.

6. The semiconductor device of claim 1, wherein side surfaces of the third region of the isolation pattern are continuously with side surfaces of the second region of the isolation pattern.

7. The semiconductor device of claim 1, further comprising:
an inner gate spacer on side surfaces of the first region of the isolation pattern opposite each other in the second direction; and
a gate dielectric pattern on side surfaces of the inner gate spacer.

8. The semiconductor device of claim 7, further comprising:
a first gate electrode at least partially surrounding the first channel pattern; and
a second gate electrode at least partially surrounding the second channel pattern,
wherein the inner gate spacer is between the first channel pattern and the first gate electrode, and between the second channel pattern and the second gate electrode.

9. The semiconductor device of claim 7, wherein the inner gate spacer is between an upper surface of each of the plurality of first semiconductor patterns and the gate dielectric pattern, and between an upper surface of each of the plurality of second semiconductor patterns and the gate dielectric pattern.

10. The semiconductor device of claim 7, wherein the inner gate spacer comprises at least one of SiO₂ and a low-k material.

11. A semiconductor device comprising:
a first channel pattern and a second channel pattern on a substrate;
an isolation pattern between the first channel pattern and the second channel pattern, the isolation pattern comprising a first region and a second region contacting the first channel pattern and the second channel pattern;
an inner gate spacer on side surfaces of the first region of the isolation pattern opposite each other in a first direction parallel to an upper surface of the substrate; and
a gate dielectric pattern on side surfaces of the inner gate spacer,
wherein the first region of the isolation pattern is spaced apart from the gate dielectric pattern, and
wherein, in the first direction, a width of the second region of the isolation pattern is greater than a width of the first region of the isolation pattern.

12. The semiconductor device of claim 11, wherein the inner gate spacer comprises at least one of SiO₂ and a low-k material.

13. The semiconductor device of claim 11, wherein, in the first direction parallel, a width of the first region of the isolation pattern is smaller than a width of the second region of the isolation pattern.

14. The semiconductor device of claim 11, wherein the first channel pattern comprises a plurality of first semiconductor patterns spaced apart in a second direction perpendicular to the substrate,
wherein the second channel pattern comprises a plurality of second semiconductor patterns spaced apart in the second direction, and
wherein the inner gate spacer is between upper surfaces of each of the plurality of first semiconductor patterns and the gate dielectric pattern, and between upper surfaces of each of the plurality of second semiconductor patterns and the gate dielectric pattern.

15. The semiconductor device of claim 11, further comprising:
a first gate electrode at least partially surrounding the first channel pattern; and
a second gate electrode at least partially surrounding the second channel pattern,
wherein the inner gate spacer is between the first channel pattern and the first gate electrode, and between the second channel pattern and the second gate electrode.

16. The semiconductor device of claim 11, wherein the first channel pattern comprises a plurality of first semiconductor patterns spaced apart in a second direction perpendicular to the substrate,
wherein the second channel pattern comprises a plurality of second semiconductor patterns spaced apart in the second direction,
wherein the isolation pattern further comprises a third region at a level that is higher than an uppermost first semiconductor pattern among the plurality of first semiconductor patterns and an uppermost second semiconductor pattern among the plurality of second semiconductor patterns, and
wherein, in the first direction, a width of the third region of the isolation pattern is greater than a width of the first region of the isolation pattern.

17. The semiconductor device of claim 16, wherein side surfaces of the third region of the isolation pattern extend in the first direction at a greater distance than side surfaces of the first region of the isolation pattern.

18. A semiconductor device comprising:
a first channel pattern and a second channel pattern on a substrate, wherein the first channel pattern comprises a plurality of first semiconductor patterns spaced apart in a first direction that is perpendicular to an upper surface of the substrate, and wherein the second channel pattern comprises a plurality of second semiconductor patterns spaced apart in the first direction;
a first source/drain pattern connected to the first channel pattern and a second source/drain pattern connected to the second channel pattern;
an isolation pattern between the first channel pattern and the second channel pattern, and between the first source/drain pattern and the second source/drain pattern;
a first gate electrode at least partially surrounding the first channel pattern and a second gate electrode at least partially surrounding the second channel pattern; and
a power transmission network layer on a lower surface of the substrate,
wherein the isolation pattern comprises:
a first region,
a second region contacting each of the first channel pattern and the second channel pattern, and
a third region at a level that is higher than an uppermost first semiconductor pattern among the plurality of first semiconductor patterns and an uppermost second semiconductor pattern among the plurality of second semiconductor patterns,
wherein, in a second direction parallel to the upper surface of the substrate, a width of the third region of the isolation pattern is greater than a width of the first region of the isolation pattern, and
wherein, in the second direction, a width of the second region of the isolation pattern is greater than the width of the first region of the isolation pattern.

19. The semiconductor device of claim 18, further comprising:
an inner gate spacer on side surfaces of the first region of the isolation pattern opposite each other in the second direction; and
a gate dielectric pattern on side surfaces of the inner gate spacer.

20. The semiconductor device of claim 18, wherein, in the second direction, the width of the first region of the isolation pattern is smaller than a width of the second region of the isolation pattern.
